(19) United States
(12) Patent Application Publication
(10) Pub. No.: US 2023/0223473 A1
(43) Pub. Date: Jul. 13, 2023

(54) SEMICONDUCTOR DEVICE AND ESD PROTECTION DEVICE COMPRISING THE SAME

(71) Applicant: NEXPERIA B.V., Nijmegen (NL)

(72) Inventors: Chinmoy Khaund, Nijmegen (NL); Pei Heng Hung, Nijmegen (NL); Gerrit Schoer, Nijmegen (NL)

(73) Assignee: NEXPERIA B.V., Nijmegen (NL)

(21) Appl. No.: 18/152,845

(22) Filed: Jan. 11, 2023

(30) Foreign Application Priority Data
Jan. 11, 2022 (EP) 22151047.2

(51) Int. Cl. H01L 29/78; H01L 29/06; H01L 29/10; H01L 29/40; H01L 29/66

(52) U.S. Cl. CPC H01L 29/7825; H01L 29/0653; H01L 29/1095; H01L 29/407; H01L 29/401; H01L 29/66704

(57) ABSTRACT

A silicon chip package structure, in particular a metal-oxide-semiconductor field-effect transistor (MOSFET) and method of manufacture is provided. The disclosure provides improvements to a Chip Silicon Package (CSP) structure by reducing the active area needed to be sacrificed to create a drain area.

### CROSS-REFERENCE TO RELATED APPLICATIONS

This application claims the benefit under 35 U.S.C. § 119(a) of European Application No. 22151047.2 filed Jan. 11, 2022, the contents of which are incorporated by reference herein in their entirety.

### BACKGROUND

### 1. Field of the Disclosure

The disclosure relates to a silicon chip package structure in particular a structure for metal-oxide-semiconductor field-effect transistor (MOSFET) and a method of manufacturing a silicon chip package structure in particular a metal-oxide-semiconductor field-effect transistor (MOSFET).

### 2. Description of the related art

Wafer level chip-scale packaging yields a semiconductor package having dimensions similar to or slightly larger than a semiconductor die. Generally, the semiconductor packages are formed on a wafer having a plurality of semiconductor dies and then diced from the wafer into individual packages.

In the case of the Chip Silicon Package (CSP), the source and the gate contact areas are usually on the front side of the chip while the drain is on a metalized backside of the chip. In power MOSFET wafer level chip-scale packages, the drain must be extended to the front side of the chip or a common drain structure including two dies may be used, so that solder balls for electrical connection to a printed circuit board can be formed on metal pads on the same front side of a chip. However, in each case, the metalized backside is still necessary.

In known CSP single side products, dedicated active area was sacrificed to create a drain area. As a result the Rdson is sacrificed. In order to overcome this drawback a new novel gate design and redistribution layer approach is suggested.

### SUMMARY

Various example embodiments are directed to issues such as those addressed above and/or others which may become apparent from the following disclosure concerning improving the CSP structure by reducing the active area needed to sacrifice to create a drain (D) area.

In certain example embodiments, aspects of the present disclosure relate to a silicon chip package structure in particular to a metal-oxide-semiconductor field-effect transistor (MOSFET), the silicon chip package structure comprising: a silicon substrate having a first substrate surface side and a second substrate surface side opposite to the first substrate surface side, a silicon body having a first body surface side and a second body surface side opposite to the first body surface side, and provided with its second body surface side to the first substrate surface side of the silicon substrate, the silicon body comprising an epitaxial layer (EPI) at its second body surface side functioning as a channel and a body well layer at its first body surface side functioning as a drift region, at least one drain (D), at least one source (S) and at least one gate (G), wherein the source (S) and the drain (D) are provided at the first body surface side of the silicon body and the gate (G) is formed as a trench positioned between the source (S) and the drain (D) and extending from the first body surface side of the silicon body through the body well layer into the epitaxial layer (EPI), the gate (G) trench being insulated from the body well layer with a LOCOS layer and the epitaxial layer (EPI) with a gate (G) oxidation layer (GOX), wherein the gate (G) trench is formed of two stacked gate (G) trench segments (Poli1, Poli2) isolated from each other by means of a LOCOS layer, each stacked gate (G) trench segment being electronically connected to a respective gate (G) terminal.

In a preferred example, the silicon chip package preferably comprises at least n drain (D) terminals and at least n source (S) terminals alternately positioned relative to each other, thereby forming at least n sets of pairs of one drain (D) and one source (S) and at least n stacked gate (G) trenches, each stacked gate (G) trench positioned between alternating drains and sources, with n being 2 or more.

In a further example, seen in a direction parallel to a longitudinal orientation of the gate (G) trench, the gate (G) terminal of one stacked gate (G) trench segment extends at a further distance from the gate (G) trench compared to the gate (G) terminal of the other stacked gate (G) trench segment.

In particular, the silicon chip package structure preferably further comprises at least a layer of isolating material comprising a conductive material circuit pattern comprising circuit section connected to the trench gate (G), the source (S) and the drain (D) accordingly.

Preferably, for connectivity reasons, the second side of the silicon substrate is connected to ground potential (GND).

In a preferred example of the silicon chip package structure according to the disclosure the gate (G) is made from a polysilicon material.

Alternatively, a thickness of the gate (G) oxidation layer insulating the stacked gate (G) trench segment closest to the first body surface side of the silicon body is thicker than a thickness of the gate (G) oxidation layer insulating the other stacked gate (G) trench segment furthest to the first body surface side of the silicon body (120).

According to an example of the disclosure a method of manufacturing a silicon chip package structure, in particular a metal-oxide-semiconductor field-effect transistor (MOSFET) is provided, the method comprising the steps of:
a. providing a silicon substrate having a first substrate surface side and a second substrate surface side opposite to the first substrate surface side;
b. providing a semiconductor epitaxial layer (EPI) on the first substrate surface side of the silicon substrate;
c. pad oxide forming a SiO₂ layer on the epitaxial layer (EPI);
d. providing a body well layer on the semiconductor epitaxial layer (EPI);
e. forming of N-well (N) and P-well (P);
f. providing thermal treatment;
g. applying hard mask treatment (HM);
h. forming a gate (G) trench (130) through etching;
i. performing first sacrificial (SAC) oxidation;
j. performing threshold voltage implementation (VT IMP) at the bottom of the trench through the sacrificial (SAC) oxidation;
k. removing sacrificial (SAC) oxidation and depositing a gate oxidation layer (GOX);
l. depositing and etching a first polysilicon layer of gate (G) layer (Poli1) in the trench;
m. performing local oxidation of silicon process (LOCOS);
n. depositing and etching a second polysilicon layer of gate (G) layer (Poli2) in the trench on the first polysilicon layer of gate (G) layer (Poli1);
o. implementing a source (S), a drain (D) and bulk implants on the first top of the silicon chip package structure;
p. encapsulating thereby forming the silicon chip package structure.

In particular the method according to the disclosure uses borophosphosilicate glass for the encapsulation step.

In a further detailed example of the method according to the disclosure, contacts are formulated by metal deposition followed by etching the circuit pattern.

Additionally, the step of encapsulation is repeated at least two times thereby forming a multilayer encapsulation.

In a further detailed example, the contacts in the encapsulation layer are formed by holes filled with conductive material.

According to an embodiment there is also provided an electronic active element comprising a metal base with a heat sink, a polymer body, at least two electrodes and the silicon chip package structure, wherein the source (S) terminal, the drain (D) terminal and the gate (G) terminal are connected to one of the two electrodes or the metal base accordingly, and wherein the silicon chip package structure (100) is encapsulated in the polymer body with at least a part of the electrodes and metal base being exposed.

### BRIEF DESCRIPTION OF DRAWINGS

The disclosure will now be discussed with reference to the drawings, which show in:

FIG. 1 shows schematic cross section of a CSP product.

FIG. 2A shows a schematic cross section of a CSP product and depicts a one gate (G) approach.

FIG. 2B shows a schematic cross section of a CSP product and depicts a split gate (G) approach.

FIGS. 3A, 3B and 3C show schematic upper views of three possible layout implementations.

FIGS. 4a, 4b, 4c, 4d, 4e, 4f, 4g, 4h, 4i, 4j, 4k, and 4l shows a schematic representation of steps for manufacturing a CSP product according to the disclosure.

FIG. 5 shows schematic cross sections of a CSP product in different locations.

FIG. 6 shows schematic cross sections of a multigame CSP product.

FIG. 7 shows schematic cross sections of CSP product manufacturing steps results.

FIG. 8 shows schematic upper views of a CSP product in a first example, and a second example.

FIG. 9 shows schematic upper views of a CSP product in a third example, and a fourth example.

FIG. 10 shows a schematic upper view of a CSP product in a fifth example.

### DETAILED DESCRIPTION

In certain examples, aspects of the present disclosure relate to a silicon chip package (100) structure in particular to a metal-oxide-semiconductor field-effect transistor (MOSFET). The silicon chip package structure (100) relates to a silicone active electronic element having a multilayer structure, in some embodiments those layers can be formed by different materials or by the same material with different structural characteristics or dopants.

In some examples, different layers can be formed with the same material having same structure and same dopants (or no dopants at all) but those layers are deposited in fewer steps of the same depositing process (PVD, CVD and others known epitaxial layer (EPI) deposition methods) or using different depositing processes.

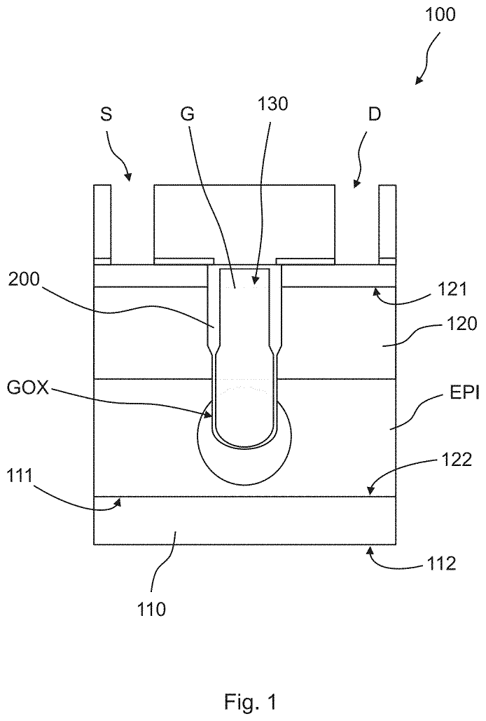

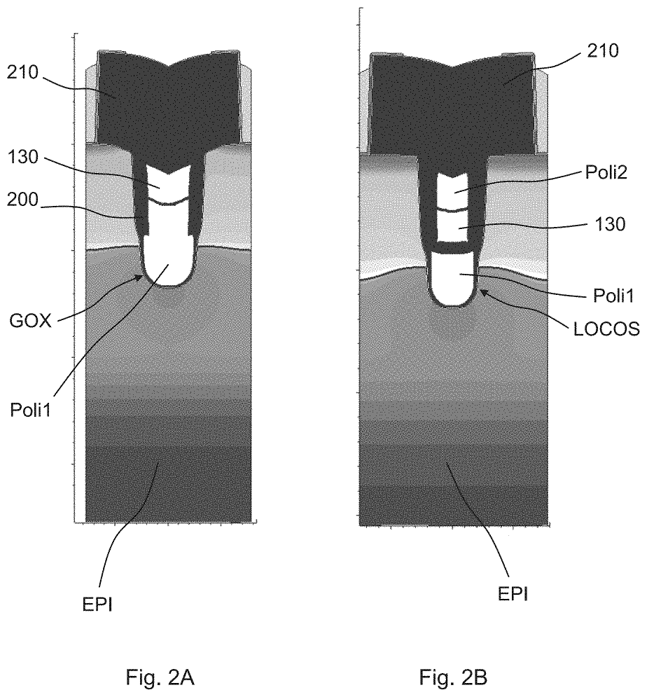

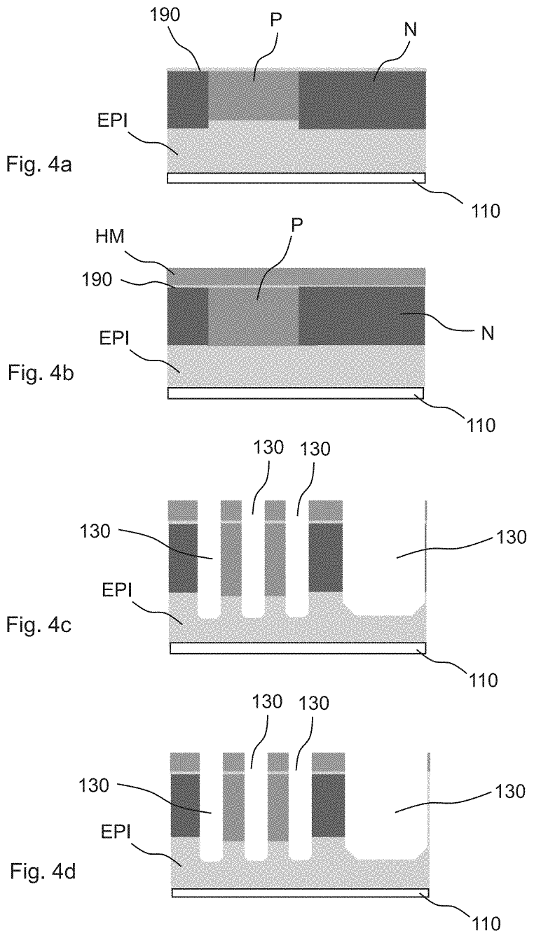

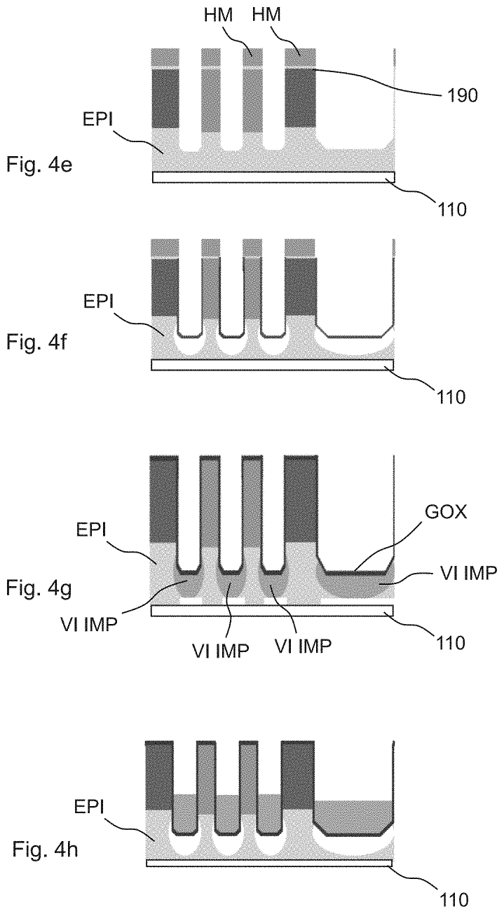

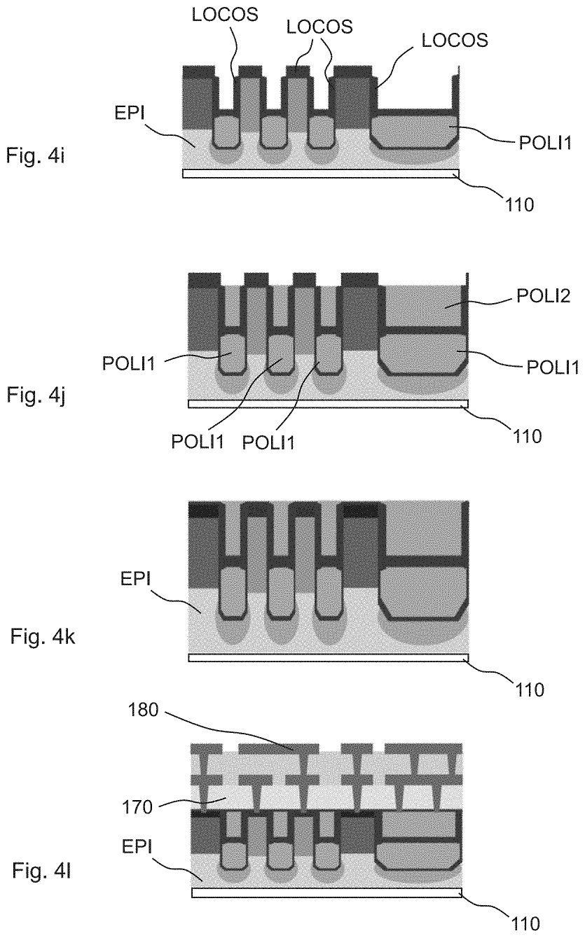

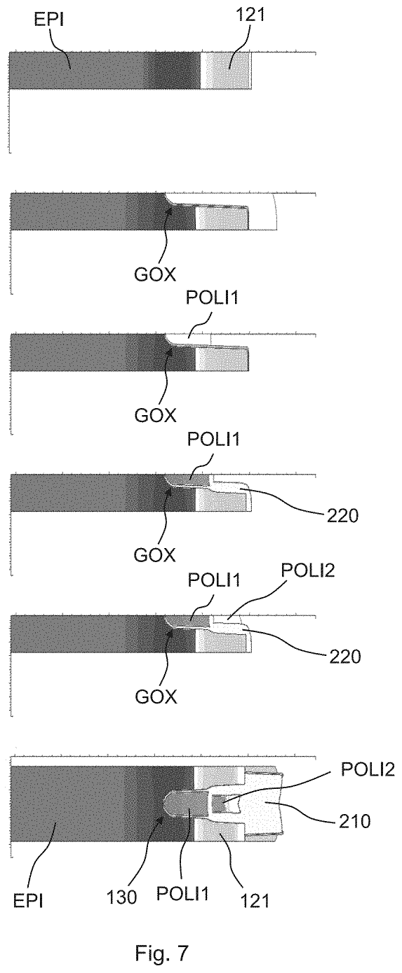

In a particular example (FIG. 1 and FIGS. 2A-2B) the silicon chip package structure (100) comprises a silicon substrate (110) having a first substrate surface side (111) and a second substrate surface side (112) opposite to the first substrate surface side (111). The silicon chip package (100) structure further comprises a silicon body (120) having a first body surface side (121) and a second body surface side (122) opposite to the first body surface side (121), and provided with its second body surface side (122) to the first substrate surface side (111) of the silicon substrate (110), the silicon body (120) comprising an epitaxial layer (EPI) at its second body surface side (122) functioning as a channel and a body well layer at its first body surface side (121) functioning as a drift region. Reference numeral (200) denotes a field oxide layer which is a relatively thick oxide (typically 100-500 nm) formed to passivate and protect the gate from the source and drain regions. This layer (200) is formed during the LOCOS process, and thus also called a LOCOS layer and will be described in more detail with reference to the step performed in FIG. 4i. In FIGS. 2A-2B and 7 reference numeral (210) may denote an ILD layer (or Inter Level Dielectric layer) used to electrically separate or shield closely spaced interconnect lines. Similarly, in the Figures reference numeral (220) denotes a shield oxide layer.

The second side (112) of the silicon substrate (110) can be connected to ground potential (GND).

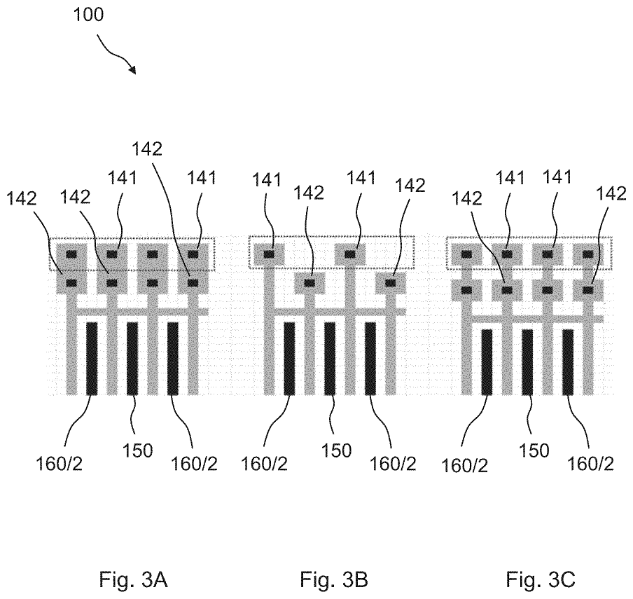

At least one drain (D), at least one source (S) and at least one gate (G) is provided, wherein the source (S) and the drain (D) are provided at the first body surface side (121) of the silicon body (120) and the gate (G) is formed as a trench (130) positioned between the source (S) and the drain (D) and extending from the first body surface side (121) of the silicon body (120) through the body well layer into the epitaxial layer (EPI), the gate (G) trench (130) being insulated from the body well layer with a LOCOS layer (200) and the epitaxial layer (EPI) with a gate (G) oxidation layer (GOX). See FIG. 2A for a cross section of the example outlined above, as well as FIGS. 3A and 3C.

FIG. 2B discloses another example according to the disclosure, wherein the gate (G) trench (130) is formed of two stacked gate (G) trench segments (Poli1, Poli2) isolated from each other by means of a LOCOS layer. Each stacked gate (G) trench (130) segment can be electronically connected to a respective gate (G) terminal (141, 142). See also FIG. 3B.

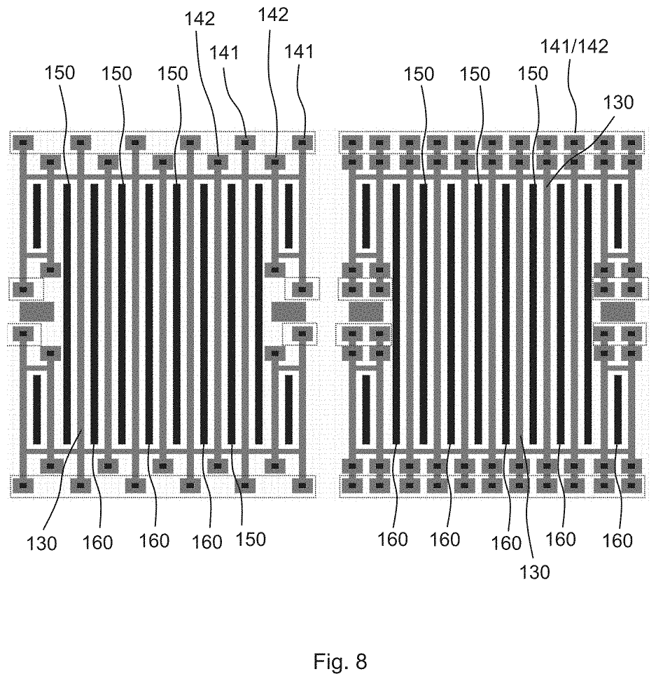

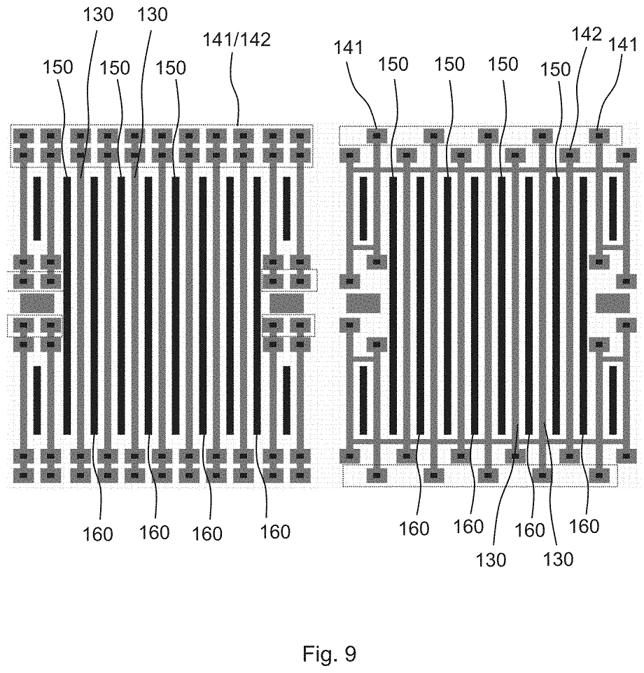

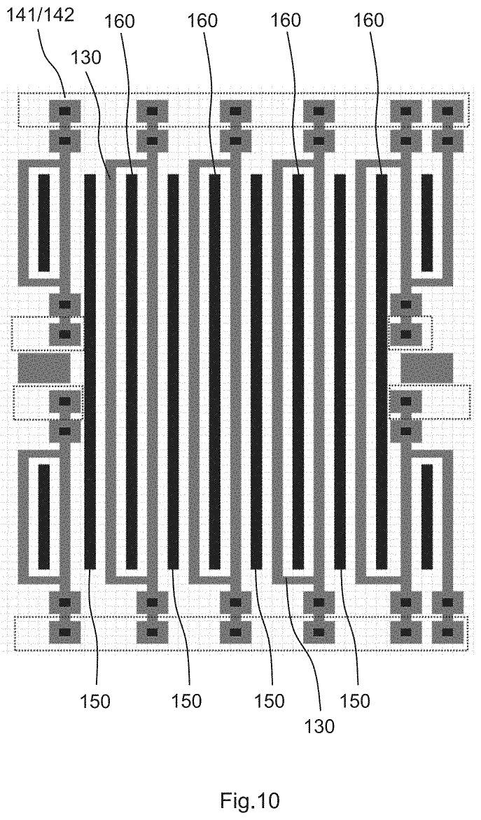

The silicon chip package (100) preferably comprises at least n drain (D) terminals (150) and at least n source (S) terminals (160) which are alternately positioned relative to each other. See FIGS. 3A-3C, FIG. 6, FIG. 8-10. Accordingly, these configurations as shown in the Figures form at least n sets of pairs of one drain (D, 150) and one source (S, 160) and at least n stacked gate (G) trenches (130), wherein each stacked gate (G) trench (130) is positioned between alternating drains (D, 150) and sources (S, 160).

It is noted, that the number n of sets of drain terminals and source terminals is at least two, and preferably 2 or more.

As shown in the drawings (FIGS. 3, 5, 8-10), the gate (G) terminal (141, 142) of one stacked gate (G) trench (130) segment extends, seen in a direction parallel to a longitudinal orientation of the gate (G) trench (130), at a further distance from the gate (G) trench (130) compared to the gate (G) terminal (141, 142) of the other stacked gate (G) trench (130) segment.

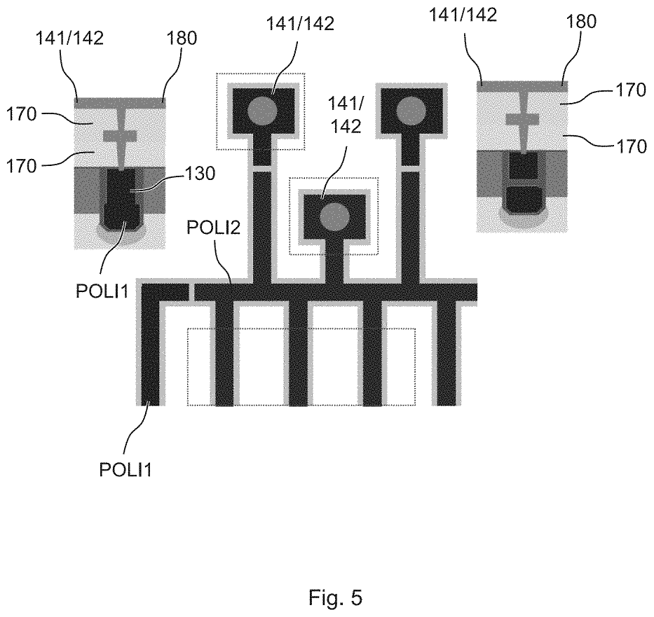

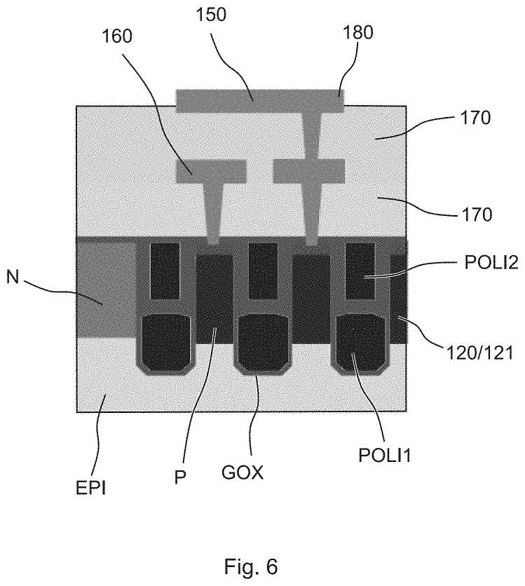

As depicted in FIGS. 5 and 6, the silicon chip package structure (100) may comprise at least a layer of isolating material (170). The layer of isolating material (170) comprises a conductive material circuit pattern (180) comprising a circuit section which is connected to the trench gate (G), the source (S, 160) and the drain (D, 150).

Suitable materials of the gate (G) comprises a polysilicon material.

As clearly shown in FIG. 1, it should be noted that the thickness of the LOCOS layer (200) which is insulating the stacked gate (G) trench (130) segment closest to the first body surface side (121) of the silicon body (120) is thicker than a thickness of the gate (G) oxidation layer (GOX) insulating the other stacked gate (G) trench (130) segment furthest to the first body surface side (121) of the silicon body (120), in fact closer to the second body surface side (122) of the silicon body (120). The gate structure with the thin GOX layer acts as a channel and the gate structure with thicker oxide (LOCOS) acts as a drift to sustain breakdown voltage (BVDSS).

The method of manufacturing a silicon chip package structure (100) in particular a metal-oxide-semiconductor field-effect transistor (MOSFET) according to the disclosure is depicted in FIGS. 4a-4l, the method comprising the steps of:
a. in FIG. 4a, providing a silicon substrate (110) having a first substrate surface side (111) and a second substrate surface side (112) opposite to the first substrate surface side;
b. in FIG. 4a, providing a semiconductor epitaxial layer (EPI) on the first substrate surface side (111) of the silicon substrate (110);
c. in FIG. 4a, forming a SiO₂ (190) layer on the epitaxial layer (EPI);
d. in FIG. 4a, providing a guard ring on the semiconductor epitaxial layer (EPI);
e. in FIG. 4a, forming of N-well (N) and P-well (P);
f. providing thermal treatment;
g. in FIG. 4b, applying hard mask treatment (HM);
h. in FIG. 4c, forming a gate (G) trench (130) through etching;
i. in FIGS. 4d-4e performing first sacrificial (SAC) oxidation;
j. in FIGS. 4d-4e, performing threshold voltage implementation at the bottom of the trench forming a threshold voltage implementation region (VT IMP) through the sacrificial (SAC) oxidation;
k. in FIGS. 4f-4g, removing sacrificial (SAC) oxidation and growing a gate (G) oxidation layer (GOX);
l. in FIG. 4h, depositing and etching a first polysilicon layer of gate (G) layer (Poli1) in the trench;
m. in FIG. 4i, performing local oxidation of silicon process forming a local oxidation of silicon layer (LOCOS), also denoted as a field oxide layer (200) see FIG. 1;
n. in FIGS. 4j-4k, depositing and etching a second polysilicon layer of gate (G) layer (Poli2) in the trench on the first polysilicon layer of gate (G) layer (Poli1);
o. in FIG. 4l implementing a source (S), a drain (D) and bulk implants on the first surface of the silicon chip package structure (100);
p. finally, encapsulating thereby forming the silicon chip package structure (100).

In certain examples borophosphosilicate glass can be used for the step of encapsulation.

The preferred example has electric contacts which are formed by metal deposition followed by the step of etching a circuit pattern. In a preferable example the step of encapsulation is repeated at least two times thereby forming a multilayer encapsulation. Further improved encapsulation can be achieved by repeating the encapsulation step preferably 3 or even 4 times.

The contacts in the encapsulation layer are formed by holes which may be filled with a conductive material, such as tungsten or any Al compound (Al, AlSi, AlCu, AlSiCu).

According to an example, the drawings also depict an electronic active element obtained with the method according to the disclosure. The electronic active element comprises a metal base with a heat sink, a polymer body, at least two electrodes and the silicon chip package structure (100) according to the disclosure. As shown in the drawings, the source (S) terminal (160), the drain (D) terminal (150) and the gate (G) terminal (141, 142) are connected to one of the two electrodes or the metal base. The silicon chip package structure (100) is encapsulated in the polymer body with at least a part of the electrodes and metal base being exposed.

The gate oxide layer (GOX) is the dielectric layer that separates the gate terminal of a MOSFET (metal-oxide-semiconductor field-effect transistor) from the underlying source and drain terminals as well as the conductive channel that connects source and drain when the transistor is turned on. The gate oxide layer (GOX) may be formed by thermal oxidation of the silicon of the channel in order form a thin insulating layer of silicon dioxide (SAC) having a thickness of 5-200 nm. The insulating silicon dioxide layer is formed through a process of self-limiting oxidation. A conductive gate material is subsequently deposited over the gate oxide to form the transistor.

LOCOS, short for Local Oxidation of Silicon, is a microfabrication process where silicon dioxide is formed in selected areas on a silicon wafer having the Si—SiO2 interface at a lower point than the rest of the silicon surface. In the process a silicon oxide insulating structure is fabricated as a field oxide layer (200), see FIG. 1, so that the Si—SiO₂ interface occurs at a lower point than the rest of the silicon surface. The oxygen penetrates in depth of the wafer, reacts with silicon and transforms it into silicon oxide.

Sacrificial (SAC) oxide denotes a semiconductor process flow technique that adds and thereafter removes a sacrificial dielectric layer to smoothen surfaces and/or remove defects from a grown or etched silicon surface.

### LIST OF REFERENCE NUMERALS

100 silicon chip package structure
110 silicon substrate
111 first substrate surface side
112 second substrate surface side
120 silicon body
121 first body surface side
122 second body surface side
130 gate trench
141, 142 gate (G) terminal
150 drain (D) terminal
160 source (S) terminal
170 layer of insulating material
180 conductive material circuit pattern
200 field oxide layer
210 ILD/Inter Level Dielectric layer
220 shield oxide layer

What is claimed is:

1. A silicon chip package structure, the silicon chip package structure comprising:
a silicon substrate having a first substrate surface side and a second substrate surface side opposite to the first substrate surface side;
a silicon body silicon body having a first body surface side and a second body surface side opposite to the first body surface side, and provided with its second body surface side to the first substrate surface side of the silicon substrate, the silicon body comprising an epitaxial layer at its second body surface side configured as a channel and a body well layer at its first body surface side configured as a drift region;
at least one drain, at least one source and at least one gate, wherein the source and the drain are provided at the first body surface side of the silicon body and the gate is formed as a trench positioned between the source and the drain and extending from the first body surface side of the silicon body through the body well layer into the epitaxial layer, the gate trench being insulated from the body well layer with a local oxidation of silicon (LOCOS) layer and the epitaxial layer with a gate oxidation layer, wherein the gate trench is formed of two stacked gate trench segments isolated from each other by means of a LOCOS layer, each stacked gate trench segment being electronically connected to a respective gate terminal.

2. The silicon chip package structure according to claim 1, further comprising at least n drain terminals and at least n source terminals alternately positioned relative to each other, thereby forming at least n sets of pairs of one drain and one source and at least n stacked gate trenches, each stacked gate trench positioned between alternating drains and sources, with n being 2 or more.

3. The silicon chip package structure according to claim 1, wherein, seen in a direction parallel to a longitudinal orientation of the gate trench, the gate terminal of one stacked gate trench segment extends at a further distance from the gate trench compared to the gate terminal of the other stacked gate trench segment.

4. The silicon chip package structure according to claim 1, further comprising at least a layer of isolating material comprising a conductive material circuit pattern comprising circuit section connected to the trench gate, the source and the drain.

5. The silicon chip package structure according to claim 1, wherein the second side of the silicon substrate is connected to ground potential.

6. The silicon chip package structure according to claim 1, wherein the gate is made from a polysilicon material.

7. The silicon chip package structure according to claim 1, wherein the gate oxidation layer insulating the stacked gate trench segment closest to the first body surface side of the silicon body has a thickness that is thicker than a thickness of the gate oxidation layer insulating the other stacked gate trench segment furthest to the first body surface side of the silicon body.

8. The silicon chip package structure according to claim 2, wherein, seen in a direction parallel to a longitudinal orientation of the gate trench, the gate terminal of one stacked gate trench segment extends at a further distance from the gate trench compared to the gate terminal of the other stacked gate trench segment.

9. The silicon chip package structure according to claim 2, further comprising at least a layer of isolating material comprising a conductive material circuit pattern comprising circuit section connected to the trench gate, the source and the drain.

10. The silicon chip package structure according to claim 2, wherein the second side of the silicon substrate is connected to ground potential.

11. The silicon chip package structure according to claim 2, wherein the gate is made from a polysilicon material.

12. The silicon chip package structure according to claim 2, wherein the gate oxidation layer insulating the stacked gate trench segment closest to the first body surface side of the silicon body has a thickness that is thicker than a thickness of the gate oxidation layer insulating the other stacked gate trench segment furthest to the first body surface side of the silicon body.

13. A method of manufacturing a silicon chip package structure in particular a metal-oxide-semiconductor field-effect transistor according to claim 1, the method comprising the steps of:
a. providing a silicon substrate having a first substrate surface side and a second substrate surface side opposite to the first substrate surface side;
b. providing a semiconductor epitaxial layer on the first substrate surface side of the silicon substrate;
c. pad oxide forming a SiO2 layer on the epitaxial layer;
d. providing a body well layer on the semiconductor epitaxial layer;
e. forming of N-well and P-well;
f. providing thermal treatment;
g. applying hard mask treatment;
h. forming a gate trench through etching;
i. performing first sacrificial oxidation;
j. performing a threshold voltage implementation at the bottom of the trench through the sacrificial oxidation;
k. removing sacrificial oxidation and depositing a gate oxidation layer;
l. depositing and etching a first polysilicon layer of gate layer in the trench;
m. performing local oxidation of silicon process;
n. depositing and etching a second polysilicon layer of gate layer in the trench on the first polysilicon layer of gate layer;
o. implementing a source, a drain and bulk implants on the first top of the silicon chip package structure; and
p. encapsulating thereby forming the silicon chip package structure.

14. The method according to claim 13, wherein borophosphosilicate glass is used for encapsulation.

15. The method according to claim 13, wherein contacts are formulated by metal deposition followed by etching a circuit pattern.

16. The method according to claim 13, wherein the step of encapsulation is repeated at least two times thereby forming a multilayer encapsulation.

17. The method according to claim 13, wherein the contacts in the encapsulation layer are formed by holes filled with conductive material.

18. The method according to claim 14, wherein contacts are formulated by metal deposition followed by etching a circuit pattern.

19. An electronic active element comprising a metal base with a heat sink, a polymer body, at least two electrodes and the silicon chip package structure according to claim 1, wherein the source terminal, the drain terminal and the gate terminal are connected to one of the two electrodes or the metal base accordingly, and wherein the silicon chip package structure is encapsulated in the polymer body with at least a part of the electrodes and metal base being exposed.

20. The silicon chip package structure according to claim 1, wherein the silicon chip package structure is a metal-oxide-semiconductor field-effect transistor (MOSFET)
